(19) United States
(12) Patent Application Publication
(10) Pub. No.: US 2026/0107720 A1
(43) Pub. Date: Apr. 16, 2026

(54) SUBSTRATE TRIMMING APPARATUS AND SUBSTRATE PROCESSING EQUIPMENT INCLUDING THE SAME

(71) Applicant: SAMSUNG ELECTRONICS CO., LTD., Suwon-si (KR)

(72) Inventors: Heejung KIM, Suwon-si (KR); Jaeho HONG, Suwon-si (KR)

(73) Assignee: SAMSUNG ELECTRONICS CO., LTD., Suwon-si (KR)

(21) Appl. No.: 19/347,865

(22) Filed: Oct. 2, 2025

(30) Foreign Application Priority Data
Oct. 10, 2024 (KR) 10-2024-0138023

(51) Int. Cl. H01L 21/304; H01L 21/67; H01L 21/68

(52) U.S. Cl. CPC H10P 52/00; H10P 72/0408; H10P 72/0414; H10P 72/0428; H10P 72/53

(57) ABSTRACT

A substrate trimming apparatus includes a support configured to support a bonding substrate including at least two substrates bonded to each other, a waterjet cutting unit arranged to face an upper surface of the support and configured to trim an edge area of the bonding substrate by discharging pressurized fluid, and a camera unit configured to sense the trimmed edge area of the bonding substrate, in which the waterjet cutting unit includes a water body through which ultrapure water passes, a mixing tube coupled to a lower portion of the water body, and an abrasive supplying unit configured to supply an abrasive, and the waterjet cutting unit is configured to discharge at least one of the ultrapure water or a mixture of the ultrapure water and the abrasive towards the edge area of the bonding substrate.

### CROSS-REFERENCE TO RELATED APPLICATION

This application is based on and claims priority under 35 U.S.C. §119 to Korean Patent Application No. 10-2024-0138023, filed on October 10, 2024, in the Korean Intellectual Property Office, the disclosure of which is incorporated by reference herein in its entirety.

### BACKGROUND

The inventive concept relates to a substrate trimming apparatus and substrate processing equipment including the same, and more particularly, to a substrate trimming apparatus with improved reliability and substrate processing equipment including the same.

According to miniaturization and high integration of chips used in semiconductor manufacturing processes, various packaging technologies have been developed. Among such technologies, the packaging technology involving a semiconductor having multilayer structure in which two bonded chips are coupled to a substrate has provided high performance and spatial efficiency and thus has been used widely in various electronic devices. To maximize the performance of the packages, precise alignment and bonding between individual chips are required, and particularly, processing of edge portions is considered as a key point.

To overcome the foregoing issues, research on the technologies to precisely process an edge area of a bonded chip into a desired shape through a trimming process has been continued.

### SUMMARY

The inventive concept provides a substrate trimming apparatus having improved reliability and accuracy and substrate processing equipment including the substrate trimming apparatus.

The object which the technical ideas of the inventive concept seek to achieve is not limited to the foregoing, and other objects may be clearly understood by a person skilled in the art from the description below.

According to an aspect of the inventive concept, a substrate trimming apparatus may include a support configured to support a bonding substrate including at least two substrates bonded to each other, a waterjet cutting unit arranged to face an upper surface of the support and configured to trim an edge area of the bonding substrate by discharging pressurized fluid, and a camera unit configured to sense the trimmed edge area of the bonding substrate, in which the waterjet cutting unit includes a water body through which ultrapure water passes, a mixing tube coupled to a lower portion of the water body, and an abrasive supplying unit configured to supply an abrasive, and the waterjet cutting unit is configured to discharge at least one of the ultrapure water or a mixture of the ultrapure water and the abrasive towards the edge area of the bonding substrate.

According to another aspect of the inventive concept, a substrate processing equipment may include an index module configured to receive and store a bonding substrate from outside, and a processing module configured to process the bonding substrate received from the index module, in which the processing module includes a substrate aligning apparatus configured to align the bonding substrate before trimming the bonding substrate, a substrate trimming apparatus configured to trim an edge area of the aligned bonding substrate, a substrate cleaning apparatus configured to clean the trimmed bonding substrate, a substrate drying apparatus configured to dry the cleaned bonding substrate, and a transfer robot configured to transfer the bonding substrate from a station to another among the substrate aligning apparatus, the substrate trimming apparatus, the substrate cleaning apparatus, and the substrate drying apparatus, and the substrate trimming apparatus includes a support configured to support the bonding substrate, a waterjet cutting unit arranged to face an upper surface of the support and configured to trim the edge area of the bonding substrate by discharging pressurized fluid, a camera unit configured to sense the trimmed edge area of the bonding substrate, and a suction configured to suck residues generated from the bonding substrate.

According to another aspect of the inventive concept, a substrate processing equipment may include an index module including a load chamber storing a bonding substrate received from outside and a first transfer robot configured to transfer the bonding substrate from the load chamber to a processing module, and the processing module configured to process the bonding substrate received from the index module, in which the processing module includes a substrate aligning apparatus configured to align the bonding substrate before trimming the bonding substrate and including a stage and a camera, a substrate trimming apparatus configured to trim an edge area of the aligned bonding substrate, a substrate cleaning apparatus configured to clean the trimmed bonding substrate, a substrate drying apparatus configured to dry the cleaned bonding substrate, and a second transfer robot configured to transfer the bonding substrate from a station to another among the substrate aligning apparatus, the substrate trimming apparatus, the substrate cleaning apparatus, and the substrate drying apparatus, the substrate trimming apparatus includes a support configured to support the bonding substrate, a waterjet cutting unit arranged to face an upper surface of the support and configured to trim the edge area of the bonding substrate by discharging pressurized fluid, a camera unit configured to sense the trimmed edge area of the bonding substrate, a suction configured to suck residues generated from the bonding substrate, and a controller configured to control a position of the waterjet cutting unit, a pressure of the fluid, a type of the fluid, and an operation of the suction based on parameters of the bonding substrate, which are measured by the camera unit, and the waterjet cutting unit includes a water body through which ultrapure water passes, an abrasive supplying unit configured to supply an abrasive, an abrasive body storing the abrasive received from the abrasive supplying unit, an orifice through which the ultrapure water passes, a mixing tube in which the ultrapure water and the abrasive are mixed, and a position adjusting unit configured to adjust a position and an angle of the fluid to be discharged.

### BRIEF DESCRIPTION OF THE DRAWINGS

Embodiments will be more clearly understood from the following detailed description taken in conjunction with the accompanying drawings in which:

FIG. 1 is a schematic plan view of a substrate processing equipment according to an embodiment;

FIG. 2 is a schematic cross-sectional view of a substrate aligning apparatus of FIG. 1;

FIGS. 3 and 4 are each a schematic cross-sectional view of a substrate trimming apparatus of FIG. 1;

FIG. 5 is a schematic view illustrating a trimmed substrate;

FIG. 6 is a schematic cross-sectional view of a substrate cleaning apparatus of FIG. 1;

FIG. 7 is a schematic cross-sectional view of a substrate drying apparatus of FIG. 1;

FIG. 8 is a schematic cross-sectional view illustrating an embodiment of the substrate trimming apparatus of FIG. 1;

FIGS. 9, 10, 11, 12 and 13 are each a cross-sectional view illustrating a trimming process of a bonding substrate including three or more bonded substrates; and

FIG. 14 is a schematic view of a waterjet cutting unit of FIG. 3.

### DETAILED DESCRIPTION OF THE EMBODIMENTS

Hereinafter, embodiments of the inventive concept are described in detail with reference to the accompanying drawings. In the drawings, like reference numerals denote like components, and any redundant description thereon will be omitted.

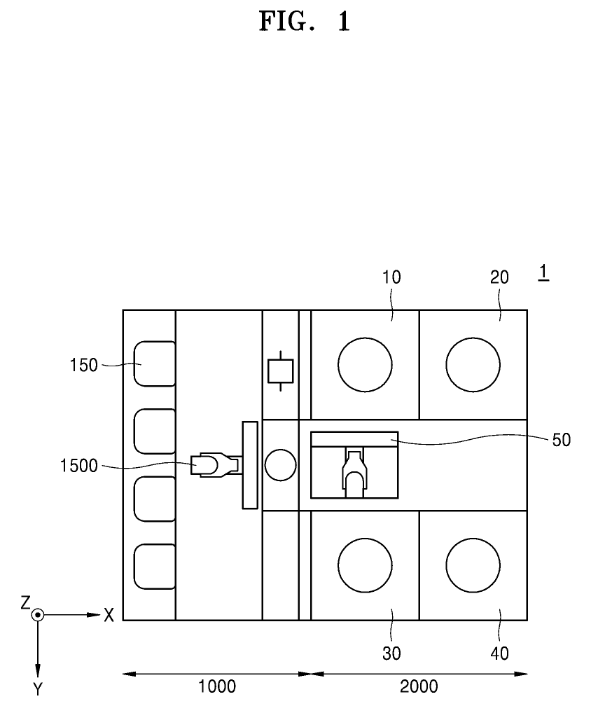

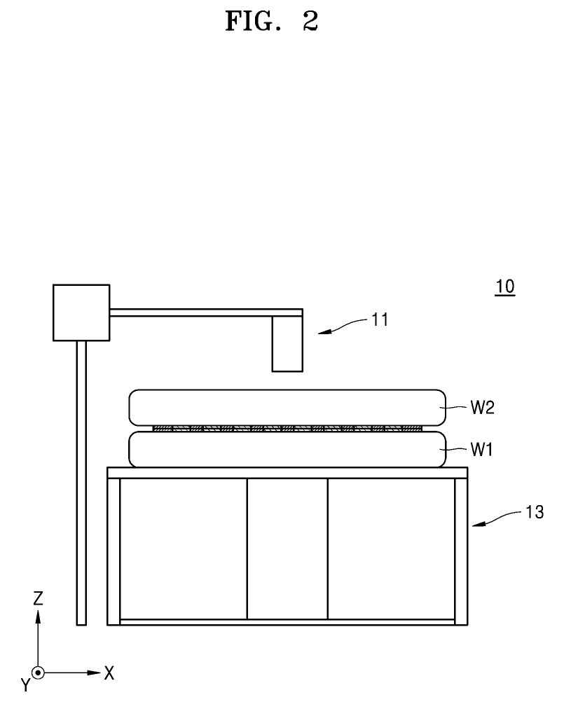

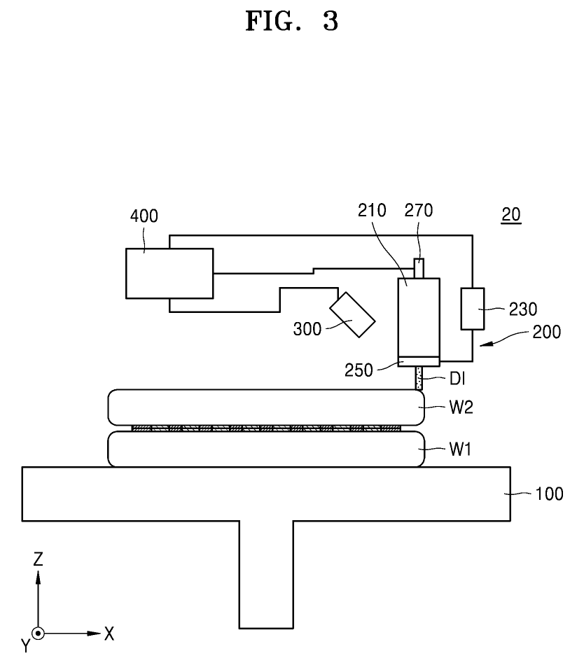

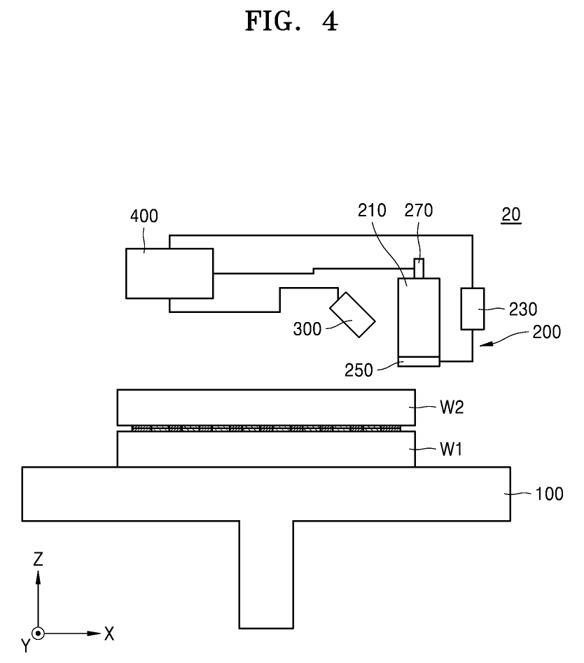

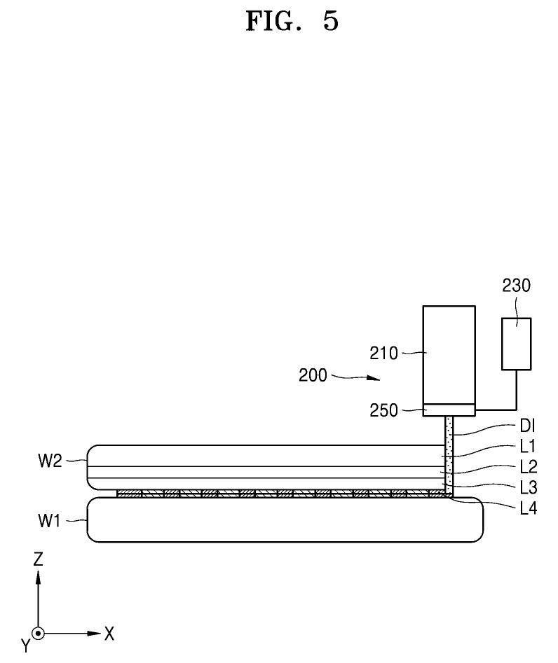

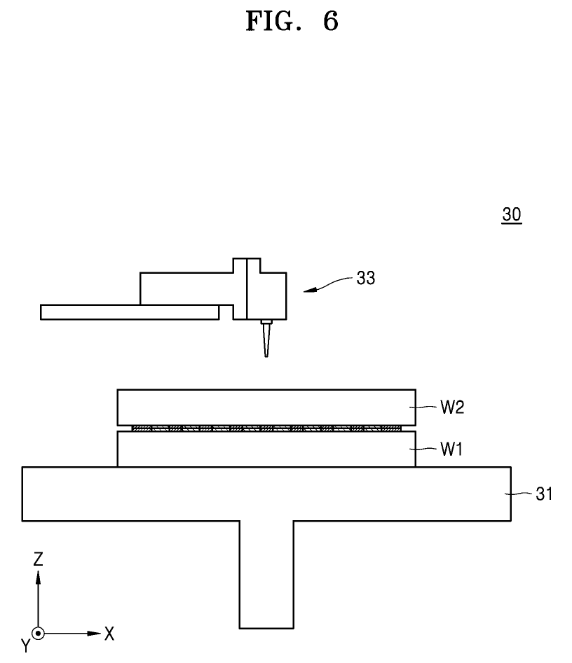

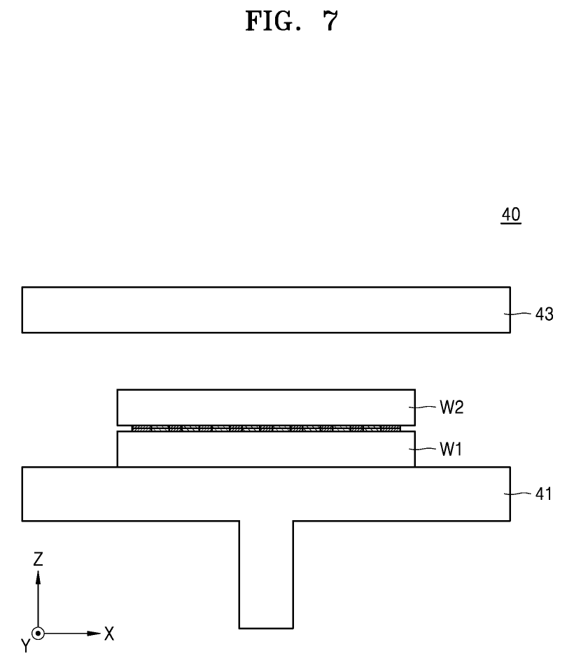

FIG. 1 is a schematic plan view of a substrate processing equipment according to an embodiment. FIG. 2 is a schematic cross-sectional view of a substrate aligning apparatus of FIG. 1. FIGS. 3 and 4 are each a schematic cross-sectional view of a substrate trimming apparatus of FIG. 1. FIG. 5 is a schematic view illustrating a trimmed substrate. FIG. 6 is a schematic cross-sectional view of a substrate cleaning apparatus of FIG. 1. FIG. 7 is a schematic cross-sectional view of a substrate drying apparatus of FIG. 1.

Referring to FIGS. 1 to 7, a substrate processing equipment 1 according to the inventive concept may include an index module 1000 and a processing module 2000. The index module 1000 may receive and keep a substrate from the outside and transfer the substrate into the processing module 2000 from the outside. The processing module 2000 may perform desired processes on the substrate received from the index module 1000. The substrate may be a substrate used for manufacture of an integrated circuit apparatus including a semiconductor apparatus or a display apparatus including a flat display apparatus. For example, the substrate may include a silicon wafer, a glass substrate, an organic substrate, a bonding substrate including a plurality of stacked substrates, etc.

In some embodiments, the substrate processing equipment 1 may be equipment for processing a bonding substrate including a plurality of stacked substrates. For example, the substrate processing equipment 1 may be equipment for trimming an edge area of the bonding substrate. To this end, the processing module 2000 of the substrate processing equipment 1 may include a substrate aligning apparatus 10, a substrate trimming apparatus 20, a substrate cleaning apparatus 30, and a substrate drying apparatus 40.

The index module 1000 may include a load chamber 150 and a transfer robot 1500. A carrier which may receive the substrate may be loaded in the load chamber 150. At least one substrate may be stored in the carrier. In some embodiments, the carrier may include a front opening unified pod (FOUP). The transfer robot 1500 may be configured to transfer the substrate between the load chamber 150 and the processing module 2000. The transfer robot 1500 may be understood as a transfer robot area (CRA). The transfer robot 1500 may transfer the substrate between the load chamber 150 and the processing module 2000 or transfer the carrier between the load chamber 150 and the processing module 2000.

In some embodiments, the transfer robot 1500 may include a hand, a robot arm, a support, and a base. The hand may be in contact with the substrate in the carrier and take the substrate out of the carrier. That is, the hand may be a part of the transfer robot 1500, which is in direct contact with the substrate. The robot arm may be combined with the hand and may be configured to perform a horizontal movement and a rotational movement. In some embodiments, the robot art may move not only in the X and Y directions but also in the Z direction. In addition, the robot arm may be configured to rotate around the X axis, the Y axis, and the Z axis. The support may be coupled to the robot arm and may provide a route for the movement of the robot arm in the Z direction. The support may have a shape extending in the Z direction. The base may be provided at a lower portion of the support. The base may fix the support. The base may provide a route for the horizontal movement of the support, e.g., movements in the X direction and/or the Y direction. In some embodiments, the base may have a shape extending in the horizontal direction.

The processing module 2000 may include the substrate aligning apparatus 10, the substrate trimming apparatus 20, the substrate cleaning apparatus 30, the substrate drying apparatus 40, and a transfer robot 50. The substrate aligning apparatus 10, the substrate trimming apparatus 20, the substrate cleaning apparatus 30, and the substrate drying apparatus 40 may be apparatuses in which the substrate is processed, and the transfer robot 50 may be a robot configured to transfer the substrate received from the index module 1000 from a station to another among the substrate aligning apparatus 10, the substrate trimming apparatus 20, the substrate cleaning apparatus 30, and the substrate drying apparatus 40.

In some embodiments, the substrate aligning apparatus 10, the substrate trimming apparatus 20, the substrate cleaning apparatus 30, and the substrate drying apparatus 40 may be provided in a 2X2 arrangement with the transfer robot 50 placed therebetween. For example, as illustrated in FIG. 1, the substrate aligning apparatus 10 and the substrate trimming apparatus 20 may be arranged side by side in the X-axis direction on the -Y-axis side of the transfer robot 50, and the substrate cleaning apparatus 30 and the substrate drying apparatus 40 may be arranged side by side in the X-axis direction on the +Y-axis side of the transfer robot 50. However, the relative arrangement of the substrate aligning apparatus 10, the substrate trimming apparatus 20, the substrate cleaning apparatus 30, and the substrate drying apparatus 40 is not limited thereto, and the substrate aligning apparatus 10, the substrate trimming apparatus 20, the substrate cleaning apparatus 30, and the substrate drying apparatus 40 may be placed freely in a 2X2 arrangement. The substrate aligning apparatus 10, the substrate trimming apparatus 20, the substrate cleaning apparatus 30, and the substrate drying apparatus 40 may be arranged side by side in line in one direction, e.g., the X-axis direction.

In the drawings, the X-axis direction may be a direction in which the substrate aligning apparatus 10, the substrate trimming apparatus 20, etc. are arranged, and the Y-axis direction may be a direction in which the substrate aligning apparatus 10, the substrate trimming apparatus 20, etc. face the transfer robot 50, or a direction in which the substrate aligning apparatus 10 and the substrate trimming apparatus 20 face the substrate cleaning apparatus 30 and the substrate drying apparatus 40 centered on the transfer robot 50 (e.g., FIG. 1). The X-axis direction and the Y-axis direction may be substantially perpendicular to each other. The Z-axis direction may be a direction substantially perpendicular to the X-axis direction and the Y-axis direction. In the drawings, a first horizontal direction, a second horizontal direction, and a vertical direction may be understood as follows. The first horizontal direction may be understood as the X-axis direction (hereinafter “X”), the second horizontal direction may be understood as the Y-axis direction (hereinafter “Y”), and the vertical direction may be understood as the Z-axis direction (hereinafter “Z”).

The substrate aligning apparatus 10 may be configured to align the substrate provided from the transfer robot 50 according to target coordinates. The substrate may be a bonding substrate including a first substrate W1 and a second substrate W2 that are stacked in the vertical direction (Z). However, the substrate is not limited to the bonding substrate. In addition, all of the substrates described below may include the bonding substrate.

In some embodiments, the substrate aligning apparatus 10 may align the position of the substrate such that the trimming process is performed on the substrate at the right position. For example, the substrate aligning apparatus 10 may adjust the position of the substrate based on a position of a waterjet cutting unit 200 of the substrate trimming apparatus 20 such that the trimming process is performed on the substrate at the right position in the substrate trimming apparatus 20.

In some embodiments, the substrate aligning apparatus 10 may include a camera 11 and a stage 13. The camera 11 may be configured to measure a position of the substrate provided on the stage 13. The stage 13 may move the substrate in at least one direction from among the first horizontal direction (X), the second horizontal direction (Y), and the vertical direction (Z), based on the position of the substrate, measured by the camera 11. In addition, the stage 13 may rotate the substrate around the Z axis. The substrate may be aligned at the right position by the stage 13.

The transfer robot 50 may transfer the substrate aligned in the substrate aligning apparatus 10 to the substrate trimming apparatus 20. The substrate trimming apparatus 20 may be configured to perform the trimming process on the substrate. For example, the substrate trimming apparatus 20 may be configured to trim an edge area of the substrate to a certain depth. As the substrate provided into the substrate trimming apparatus 20 is aligned to be fit into a trimming position by the substrate aligning apparatus 10, no additional alignment of the substrate may be necessary.

The substrate trimming apparatus 20 may include a support 100, the waterjet cutting unit 200, a camera unit 300, and a controller 400. The support 100 may be configured to support the substrate received from the transfer robot 50. The support 100 may rotate around the Z axis. The support 100 may include a base plate constituting a basic frame, a support block arranged on the base plate and in direct contact with the substrate, a vacuum adhering unit arranged on the support block and configured to fix and adhere the substrate, and a position adjusting unit configured to move the position of the support 100 along the X axis, Y axis, and Z axis or rotate the support 100 around the Z axis.

The waterjet cutting unit 200 may be configured to discharge fluid DI towards the edge area of the substrate. The waterjet cutting unit 200 may trim the edge area of the substrate by discharging the fluid DI. The fluid DI may include, for example, ultrapure water, a mixture of ultrapure water and an abrasive, etc. In some embodiments, the pressure of the fluid DI discharged from the waterjet cutting unit 200 towards the substrate may be in a range from about 4,100 bar to about 6,400 bar. In some embodiments, the speed of the fluid DI discharged towards the substrate may be in a range from about 1 mach to about 4 mach. As used herein, the expression “about” may refer to an approximate value, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ± 1%, ± 5% , or ± 10% of the actual value stated, and other suitable tolerances.

The waterjet cutting unit 200 may include a water body 210, an abrasive supplying unit 230, a mixing tube 250, and a position adjusting unit 270. The water body 210 may be a part through which high-pressure ultrapure water passes and may include a pump. In some embodiments, the ultrapure water passing through the water body 210 may be discharged directly towards the substrate without going through the mixing tube 250. In some embodiments, the ultrapure water passing through the water body 210 may be discharged towards the substrate after being mixed with an abrasive in the mixing tube 250. Accordingly, the fluid DI discharged towards the substrate may be ultrapure water or a mixture of ultrapure water and an abrasive. The fluid DI discharged from the waterjet cutting unit 200 is not limited thereto, and the fluid DI may be any fluid that can be used for trimming the substrate.

The abrasive supplying unit 230 may be configured to supply an abrasive to the mixing tube 250. The provided abrasive may be mixed with ultrapure water which has passed through the water body 210 in the mixing tube 250. The mixing tube 250 may be combined and provided with the water body 210. When the mixing tube 250 and the water body 210 are integrated with each other, the mixing tube 250 and the water body 210 may be collectively referred to as a body. A nozzle may be provided on a lower surface of the mixing tube 250. The fluid DI may be discharged from the waterjet cutting unit 200 towards the substrate through the nozzle.

The position adjusting unit 270 may be configured to adjust a position of the waterjet cutting unit 200. For example, the position adjusting unit 270 may move the waterjet cutting unit 200 in at least one direction from among the first horizontal direction (X), the second horizontal direction (Y), and the vertical direction (Z). In addition, the position adjusting unit 270 may be configured to tilt the waterjet cutting unit 200. The waterjet cutting unit 200 may be tilted to form a certain angle with the Z axis by the position adjusting unit 270. When the waterjet cutting unit 200 is tilted, the substrate may be trimmed in a diagonal direction.

In some embodiments, as illustrated in FIG. 3, the waterjet cutting unit 200 may be discharged towards the second substrate W2 and trim the second substrate W2. The waterjet cutting unit 200 may trim only the second substrate W2, trim both of the second substrate W2 and the first substrate W1 as illustrated in FIG. 4, or partially trim the second substrate W2 as illustrated in FIG. 5.

During when the waterjet cutting unit 200 discharges the fluid DI towards the substrate, the support 100 may rotate with respect to the Z-axis direction. In this manner, the entire edge area of the substrate may be trimmed.

The waterjet cutting unit 200 may discharge ultrapure water or a mixture of ultrapure water and an abrasive supplied through the abrasive supplying unit 230. By doing so, the trimming of the substrate may be performed even when the substrate includes layers having different hardnesses. For example, as illustrated in FIG. 5, the second substrate W2 may include a first layer L1, a second layer L2, a third layer L3, and a fourth layer L4. The first layer L1, the second layer L2, the third layer L3, and the fourth layer L4 may have different material properties from each other. Accordingly, changes in pressure or material of the fluid DI discharged from the waterjet cutting unit 200 may be required for trimming of each of the first layer L1, the second layer L2, the third layer L3, and the fourth layer L4. In this regard, the waterjet cutting unit 200 may change the pressure of the fluid DI through the pump included in the water body 210 and may discharge the fluid DI including an abrasive through the mixing tube 250. Accordingly, even when the second substrate W2 includes the first layer L1, the second layer L2, the third layer L3, and the fourth layer L4, types and pressure of the fluid DI suitable for the trimming of each of the first layer L1, the second layer L2, the third layer L3, and the fourth layer L4 may be provided, which facilitates the trimming of the second substrate W2.

The camera unit 300 may be configured to sense an area of the substrate trimmed by the fluid DI. For example, the camera unit 300 may sense a trimming degree, a trimming angle, a trimming speed, etc.

The controller 400 may be configured to control the waterjet cutting unit 200 based on a state of the substrate measured by the camera unit 300. For example, the controller 400 may control the pressure of the fluid DI discharged from the waterjet cutting unit 200 based on the state of the substrate measured by the camera unit 300. The controller 400 may adjust the position, cross-sectional angle, etc. of the substrate to be trimmed by controlling the position adjusting unit 270 of the waterjet cutting unit 200, based on the state of the substrate measured by the camera unit 300. In addition, when the layer of the substrate changes based on the state of the substrate measured by the camera unit 300, the controller 400 may control the type and pressure of the fluid DI discharged from the waterjet cutting unit 200.

The controller 400 may be implemented by hardware, firmware, software, or any combination thereof. For example, the controller 400 may include a computing device such as a work station computer, a desktop computer, a laptop computer, a tablet computer, etc. The controller 400 may include a basic controller, a complex processor such as a microprocessor, a central processing unit (CPU), a graphics processing unit (GPU), etc., a processor configured by software, a dedicated hardware, or a firmware. The controller 400 may be implemented by, for example, a general purpose computer or an application-specific hardware such as a digital signal process (DSP), a field programmable gate array (FPGA), an application-specific integrated circuit (ASIC), etc. The controller 400 may be implemented by commands stored on a machine-readable medium readable and executable by one or more processors. In this regard, the machine-readable medium may include any mechanism for storing and/or transmitting information in a form readable by a machine (e.g., a computing device). For example, the machine-readable medium may include read only memory (ROM), random access memory (RAM), a magnetic disk storage medium, flask memory devices, electrical, optical, acoustic, or other radio signals (e.g., carrier wave, infrared signal, digital signal, etc.), and any other signals.

The transfer robot 50 may transfer the substrate of which edge area is trimmed in the substrate trimming apparatus 20 to the substrate cleaning apparatus 30. The substrate cleaning apparatus 30 may be configured to clean the substrate provided from the transfer robot 50.

In some embodiments, the substrate cleaning apparatus 30 may include a support 31 and a cleaning unit 33. The support 31 may be configured to support the substrate and rotate around the Z axis. The cleaning unit 33 may be configured to supply a cleaning solution onto the substrate. The cleaning solution may include, for example, water such as deionized water or a chemical solution for substrate cleaning. In some embodiments, the substrate cleaning apparatus 30 may have a cup shape with open top, but not limited thereto. The substrate cleaning apparatus 30 may be an apparatus commonly used in the cleaning process of substrates.

The transfer robot 50 may transfer the substrate cleaned in the substrate cleaning apparatus 30 to the substrate drying apparatus 40. The substrate drying apparatus 40 may be configured to dry the substrate provided from the transfer robot 50.

In some embodiments, the substrate drying apparatus 40 may include a support 41 and a heat source 43. The support 41 may be configured to support the substrate. The heat source 43 may be configured to supply heat towards the substrate. The heat source 43 may use a direct heating method using heat lines or an indirect heating method using hot air and may choose a proper method according to a type of substrate and other requirements. The substrate drying apparatus 40 may further include a dehumidifier. The dehumidifier may effectively remove moisture by adjusting the humidity inside the chamber. The dehumidifier may adjust the humidity in the chamber by using, for example, a moisture-absorbing method or a cooling method.

Conventionally, the edge trimming process has been performed on a substrate, more specifically, a bonding substrate including a plurality of bonding substrates by using a mechanical method or a laser method. Accordingly, due to physical impacts applied to the bonding substrate, issues of remaining stress, microcracks, etc. may occur, and thermal deformation of the substrate may be caused by a laser. In addition, the mechanical method and the laser method may require unnecessary and many steps. Moreover, according to the mechanical method and the laser method, it may be difficult to perform uniform trimming on a substrate having various layers during the trimming process.

However, the substrate processing equipment 1 and the substrate trimming apparatus 20 according to the inventive concept may perform trimming of the edge area of the substrate through the waterjet cutting unit 200. As the waterjet cutting unit 200 is able to freely control the water pressure and the mixing degree of the fluid DI, layers having various hardnesses may be trimmed. Also, as the waterjet cutting unit 200 has a relatively fast cutting force, the productivity of the trimming process may be improved.

Furthermore, as the waterjet cutting unit 200 trims the edge area of the substrate by using fluid, the aforementioned issues of thermal deformation, remaining stress, microcracks, etc. may be prevented.

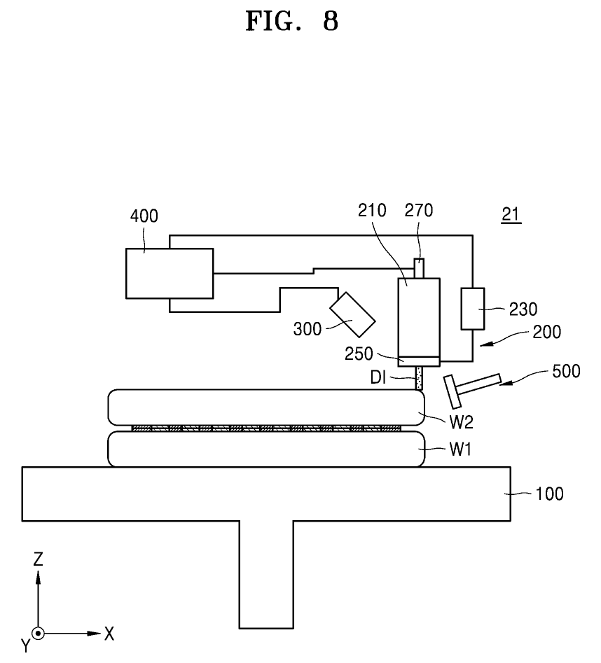

FIG. 8 is a schematic cross-sectional view illustrating an embodiment of the substrate trimming apparatus of FIG. 1. Hereinafter, differences between the substrate trimming apparatus 20 described in relation to FIGS. 1 to 7 and a substrate trimming apparatus 21 of FIG. 8 are described in detail.

Referring to FIG. 8, the substrate trimming apparatus 21 may include the support 100, the waterjet cutting unit 200, the camera unit 300, a suction 500, and the controller 400. The support 100 may be configured to support the substrate and rotate around the Z axis.

The waterjet cutting unit 200 may be configured to discharge fluid DI towards the edge area of the substrate. The waterjet cutting unit 200 may trim the edge area of the substrate by discharging the fluid DI. The waterjet cutting unit 200 may include a water body 210, an abrasive supplying unit 230, a mixing tube 250, and a position adjusting unit 270. The water body 210 may be a part through which high-pressure ultrapure water passes and may include a pump.

The abrasive supplying unit 230 may be configured to supply an abrasive to the mixing tube 250. The provided abrasive may be mixed with ultrapure water which has passed through the water body 210 in the mixing tube 250. The position adjusting unit 270 may be configured to adjust a position of the waterjet cutting unit 200. For example, the position adjusting unit 270 may move the waterjet cutting unit 200 in at least one direction from among the first horizontal direction (X), the second horizontal direction (Y), and the vertical direction (Z). In addition, the position adjusting unit 270 may be configured to tilt the waterjet cutting unit 200. The waterjet cutting unit 200 may be tilted to form a certain angle with the Z axis by the position adjusting unit 270.

The suction 500 may be configured to suck residues generated during the trimming of the substrate. In some embodiments, the suction 500 may include a suction nozzle, a suction flow path, a dust collector, a suction pump, etc. The suction nozzle may be arranged close to a surface of the substrate during the trimming process of the substrate and configured to suck the residues directly. The diameter and suction angle of the suction nozzle may be adjusted according to types of the substrate and characteristics of the residues. The suction flow path may be a path through which the residues sucked through the suction nozzle are delivered to an outside dust collector. In some embodiments, as an internal surface of the suction flow path is coated with an antistatic material having a low coefficient of friction, the residues may not adhere to the inside of the flow path. The dust collector may collect and filter the residues delivered through the suction flow path. The dust collector may include a high-efficient filtering system to effectively remove microparticles. The suction pump may be a device providing strong absorptive power to the entire suction system and may quickly suck the residues generated from the substrate and move the same to the dust collector through the flow path.

The camera unit 300 may be configured to sense an area of the substrate trimmed by the fluid DI. For example, the camera unit 300 may sense a trimming degree, a trimming angle, a trimming speed, etc. In addition, the camera unit 300 may be configured to sense parameters of the residues generated during the trimming process of the substrate. For example, the camera unit 300 may sense an amount, type, concentration, etc. of the residues generated during the trimming process of the substrate.

The controller 400 may be configured to control the waterjet cutting unit 200 and the suction 500 based on a state of the substrate measured by the camera unit 300. For example, the controller 400 may control the pressure of the fluid DI discharged from the waterjet cutting unit 200 based on the state of the substrate measured by the camera unit 300. The controller 400 may adjust the position, cross-sectional angle, etc. of the substrate to be trimmed by controlling the position adjusting unit 270 of the waterjet cutting unit 200, based on the state of the substrate measured by the camera unit 300. In addition, when the layer of the substrate changes based on the state of the substrate measured by the camera unit 300, the controller 400 may adjust the type and pressure of the fluid DI discharged from the waterjet cutting unit 200. The controller 400 may start or stop the operation of the suction 500 based on the parameters of the residues measured by the camera unit 300.

The substrate trimming apparatus 21 according to the inventive concept may efficiently and precisely trim the edge area of the bonding substrate and remove the residues generated during the trimming process through the suction 500. As a result, the reliability of the trimming process of the substrate may be improved.

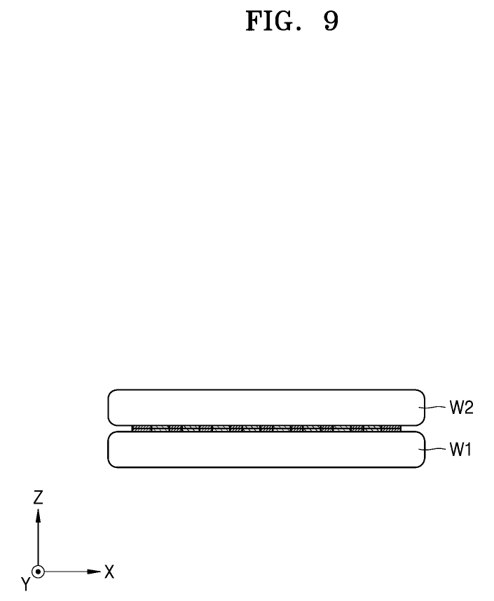

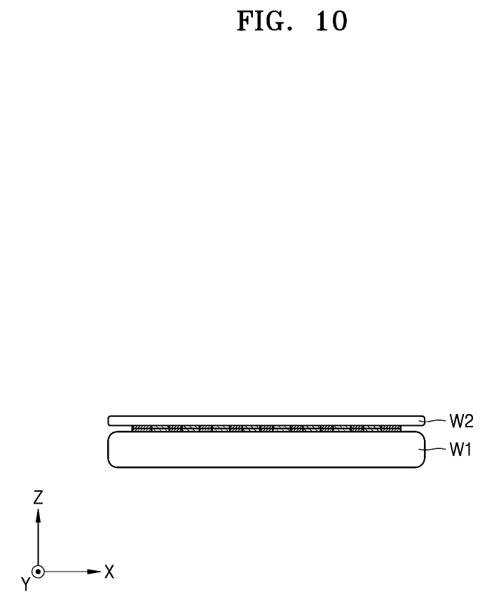

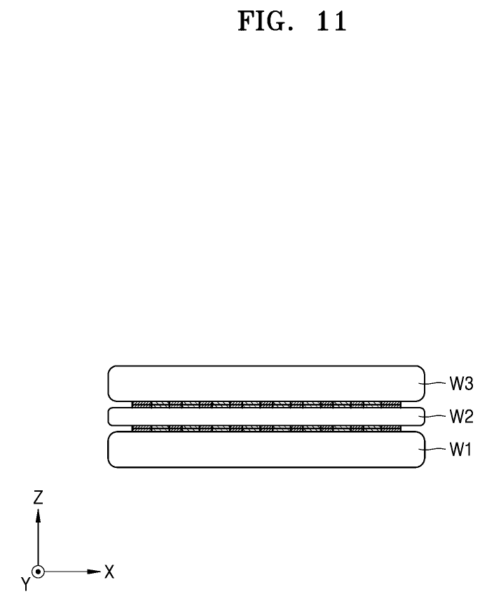

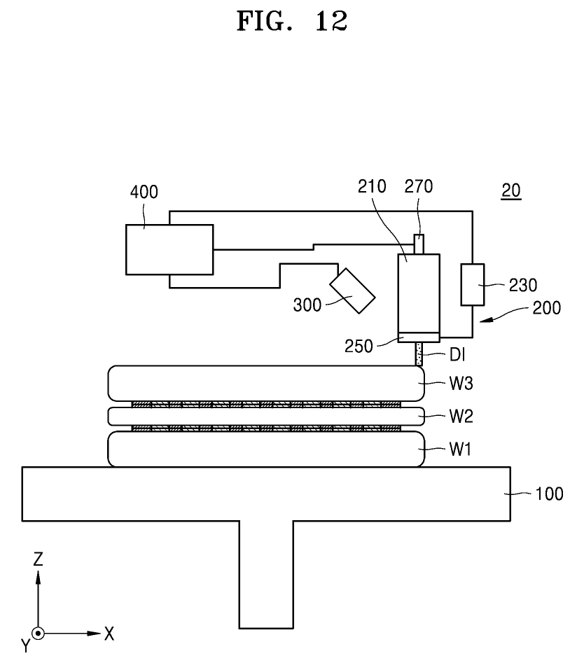

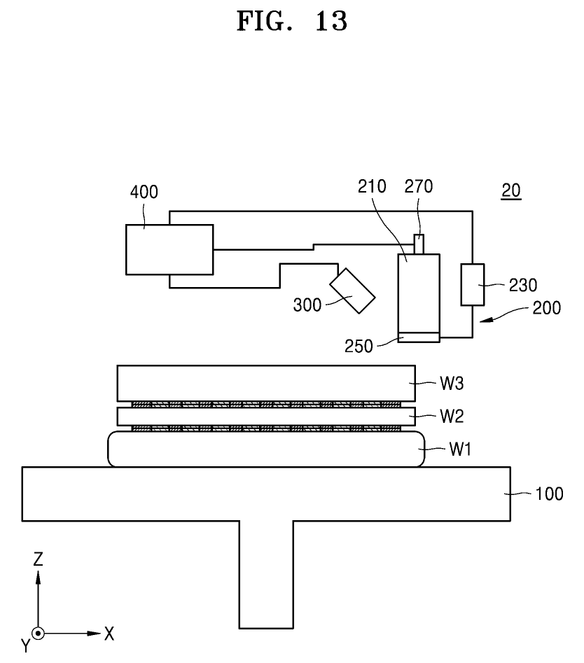

FIGS. 9 to 13 are each a cross-sectional view illustrating a trimming process of a bonding substrate including three or more bonded substrates. Hereinafter, any redundant explanation described with reference to FIGS. 1 to 8 is omitted, and the embodiments are described focusing on the differences.

First, referring to FIGS. 9 to 11, the first substrate W1 and the second substrate W2 may be bonded to each other, and the thickness of the second substrate W2 stacked on the first substrate W1 may be adjusted through a chemical mechanical planarization (CMP) process, etc. Then, after a bonding pad, an insulating layer, etc. are formed on an upper surface of the second substrate W2, and the third substrate W3 may be bonded thereto. Through this process, a bonding substrate including three or more bonded substrates may be provided. Although FIGS. 9 to 11 illustrate a case where a bonding substrate including three bonded substrates is provided, the bonding substrate may be a bonding substrate including four or more bonded substrates.

The edge of the bonding substrate including three or more bonded substrates may be trimmed by the substrate trimming apparatus 20. The substrate trimming apparatus 20 may include a support 100, the waterjet cutting unit 200, a camera unit 300, and a controller 400. The support 100 may be configured to support the substrate and rotate around the Z axis.

The waterjet cutting unit 200 may be configured to discharge fluid DI towards the edge area of the substrate. The waterjet cutting unit 200 may trim the edge area of the substrate by discharging the fluid DI. The waterjet cutting unit 200 may include the water body 210, the abrasive supplying unit 230, the mixing tube 250, and the position adjusting unit 270. The water body 210 may be a part through which high-pressure ultrapure water passes and may include a pump.

The abrasive supplying unit 230 may be configured to supply an abrasive to the mixing tube 250. The provided abrasive may be mixed with ultrapure water which has passed through the water body 210 in the mixing tube 250. The position adjusting unit 270 may be configured to adjust a position of the waterjet cutting unit 200. For example, the position adjusting unit 270 may move the waterjet cutting unit 200 in at least one direction from among the first horizontal direction (X), the second horizontal direction (Y), and the vertical direction (Z). In addition, the position adjusting unit 270 may be configured to tilt the waterjet cutting unit 200. The waterjet cutting unit 200 may be tilted to form a certain angle with the Z axis by the position adjusting unit 270.

In some embodiments, in the bonding substrate including three or more bonded substrates, only the third substrate W3 may be trimmed, both the third substrate W3 and the second substrate W2 may be trimmed, or all of the third substrate W3, the second substrate W2, and the first substrate W1 may be trimmed by the waterjet cutting unit 200. In addition, in the bonding substrate including three or more bonded substrates, only some of the layers of the third substrate W3 may be trimmed.

As the waterjet cutting unit 200 may freely control the fluid pressure, type, etc. of the fluid DI, even when the substrates (W1, W2, and W3) having different hardnesses from each other are bonded to each other, the trimming process may be performed all at once. Accordingly, when the trimming process is performed on the bonding substrate including three or more bonded substrates by the waterjet cutting unit 200, the complete trimming process may need to be performed only once after the final bonding of the substrates. Thus, the trimming process of the substrate may be simplified, and the reliability of the trimming process may be improved.

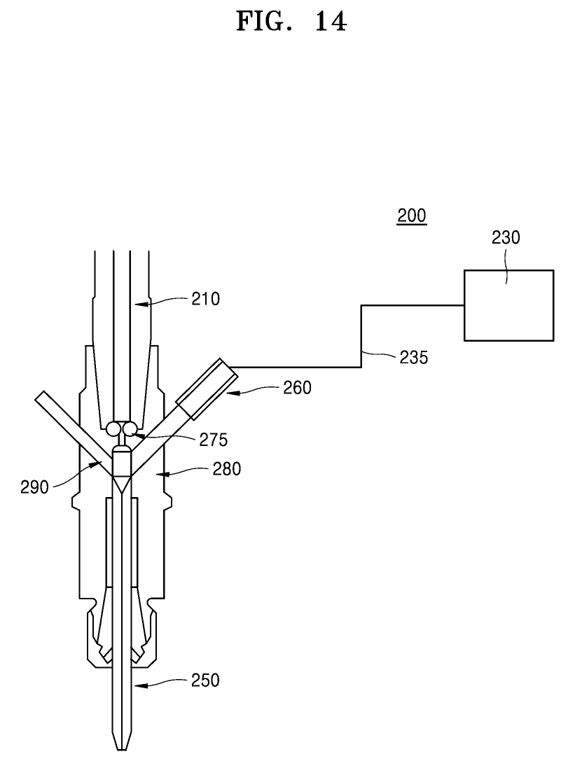

FIG. 14 is a schematic view of the waterjet cutting unit of FIG. 3. Hereinafter, any redundant explanation described with reference to FIGS. 1 to 13 is omitted, and the embodiments are described focusing on the differences.

The waterjet cutting unit 200 may include the water body 210, the abrasive supplying unit 230, an abrasive supply line 235, an abrasive inlet 260, an orifice 275, an abrasive body 280, an abrasive auxiliary port 290, and the mixing tube 250. The water body 210 may be a part through which high-pressure water passes and may form a high-speed water jet. The water body 210 may discharge high-speed water towards the orifice 275.

The abrasive supplying unit 230 may provide the abrasive to the abrasive inlet 260 through the abrasive supply line 235. The abrasive inlet 260 may be a path for the abrasive to the inside of the water body 210. The orifice 275 may include a narrow hole through which the high-pressure water passes and is converted into high-speed water jet. The orifice 275 may control the width and speed of the water jet.

The abrasive body 280 may be a space where the abrasive stays temporarily and may store the abrasive before the abrasive is mixed with the water. The abrasive may be mixed with the water in the abrasive body 280. The abrasive auxiliary port 290 may be an auxiliary port which facilitates the mixing of the abrasive and the water sprayed from the orifice 275. The abrasive may be stably supplied to the water jet through the abrasive auxiliary port 290.

The mixing tube 250 may be a space where the high-pressure water and the abrasive are mixed. The water and the abrasive may uniformly mixed with each other by passing through the mixing tube 250, and the mixture of the abrasive and the water may be converted into a cutting jet having high energy.

While the inventive concept has been particularly shown and described with reference to embodiments thereof, it will be understood that various changes in form and details may be made therein without departing from the spirit and scope of the following claims.

What is claimed is:

1. A substrate trimming apparatus comprising:
a support configured to support a bonding substrate including at least two substrates bonded to each other;
a waterjet cutting unit arranged to face an upper surface of the support and configured to trim an edge area of the bonding substrate by discharging pressurized fluid; and
a camera unit configured to sense the trimmed edge area of the bonding substrate,
wherein the waterjet cutting unit includes a water body through which ultrapure water passes, a mixing tube coupled to a lower portion of the water body, and an abrasive supplying unit configured to supply an abrasive, and
the waterjet cutting unit is configured to discharge at least one of the ultrapure water or a mixture of the ultrapure water and the abrasive towards the edge area of the bonding substrate.

2. The substrate trimming apparatus of claim 1, wherein a pressure of the fluid is in a range from about 4,100 bar to about 6,400 bar.

3. The substrate trimming apparatus of claim 1, wherein the waterjet cutting unit further includes a position adjusting unit configured to:
move the waterjet cutting unit in at least one direction of a first horizontal direction, a second horizontal direction, or a vertical direction different from the first and second horizontal directions, and
tilt the waterjet cutting unit to form a certain angle from a Z axis of the waterjet cutting unit.

4. The substrate trimming apparatus of claim 1, further comprising a suction configured to suck residues generated from the bonding substrate.

5. The substrate trimming apparatus of claim 1, further comprising a controller configured to control a position of the waterjet cutting unit, a pressure of the fluid, and a type of the fluid based on parameters of the bonding substrate, which are measured by the camera unit.

6. The substrate trimming apparatus of claim 5, wherein the parameters include at least one of a trimming degree of the bonding substrate, a trimming speed of the bonding substrate, or a type of a trimmed layer of the bonding substrate.

7. The substrate trimming apparatus of claim 1, wherein the support is configured to rotate around a Z axis of the support.

8. The substrate trimming apparatus of claim 1, wherein the bonding substrate includes a first substrate and a second substrate, and at least one of the first substrate or the second substrate includes at least two layers having different hardnesses from each other.

9. The substrate trimming apparatus of claim 1, wherein the bonding substrate includes a first substrate, a second substrate, and a third substrate, and at least some of the first substrate, the second substrate, and the third substrate have different material properties from each other.

10. The substrate trimming apparatus of claim 1, wherein the waterjet cutting unit further includes an orifice, an abrasive supply line, an abrasive body, and an abrasive auxiliary port.

11. A substrate processing equipment comprising:
an index module configured to receive and store a bonding substrate from outside; and
a processing module configured to process the bonding substrate received from the index module,
wherein the processing module includes:
a substrate aligning apparatus configured to align the bonding substrate before trimming the bonding substrate;
a substrate trimming apparatus configured to trim an edge area of the aligned bonding substrate;
a substrate cleaning apparatus configured to clean the trimmed bonding substrate;
a substrate drying apparatus configured to dry the cleaned bonding substrate; and
a transfer robot configured to transfer the bonding substrate from a station to another among the substrate aligning apparatus, the substrate trimming apparatus, the substrate cleaning apparatus, and the substrate drying apparatus, and
the substrate trimming apparatus includes:
a support configured to support the bonding substrate;
a waterjet cutting unit arranged to face an upper surface of the support and configured to trim the edge area of the bonding substrate by discharging pressurized fluid;
a camera unit configured to sense the trimmed edge area of the bonding substrate; and
a suction configured to suck residues generated from the bonding substrate.

12. The substrate processing equipment of claim 11, wherein the waterjet cutting unit includes a water body through which ultrapure water passes, an abrasive supplying unit configured to supply an abrasive, an abrasive body storing the abrasive received from the abrasive supplying unit, an orifice through which the ultrapure water passes, and a mixing tube in which the ultrapure water and the abrasive are mixed.

13. The substrate processing equipment of claim 11, wherein the substrate aligning apparatus, the substrate trimming apparatus, the substrate cleaning apparatus, and the substrate drying apparatus are aligned in a 2X2 arrangement.

14. The substrate processing equipment of claim 11, wherein the suction includes a suction nozzle, a suction flow path, a dust collector, and a suction pump.

15. The substrate processing equipment of claim 11, further comprising a controller configured to control a position of the waterjet cutting unit, a pressure of the fluid, and a type of the fluid based on parameters of the bonding substrate, which are measured by the camera unit,
wherein the parameters include at least one of a trimming degree of the bonding substrate, a trimming speed of the bonding substrate, or a type of a trimmed layer of the bonding substrate.

16. The substrate processing equipment of claim 11, wherein the bonding substrate includes a first substrate and a second substrate, and at least one of the first substrate or the second substrate includes at least two layers having different hardnesses from each other.

17. The substrate processing equipment of claim 11, wherein the bonding substrate includes a first substrate, a second substrate, and a third substrate, and at least some of the first substrate, the second substrate, and the third substrate have different material properties from each other.

18. A substrate processing equipment comprising:
an index module including a load chamber storing a bonding substrate received from the outside and a first transfer robot configured to transfer the bonding substrate from the load chamber to a processing module; and
the processing module configured to process the bonding substrate received from the index module,
wherein the processing module includes:
a substrate aligning apparatus configured to align the bonding substrate before trimming the bonding substrate and including a stage and a camera;
a substrate trimming apparatus configured to trim an edge area of the aligned bonding substrate;
a substrate cleaning apparatus configured to clean the trimmed bonding substrate;
a substrate drying apparatus configured to dry the cleaned bonding substrate; and
a second transfer robot configured to transfer the bonding substrate from a station to another among the substrate aligning apparatus, the substrate trimming apparatus, the substrate cleaning apparatus, and the substrate drying apparatus,
the substrate trimming apparatus includes:
a support configured to support the bonding substrate;
a waterjet cutting unit arranged to face an upper surface of the support and configured to trim the edge area of the bonding substrate by discharging pressurized fluid;
a camera unit configured to sense the trimmed edge area of the bonding substrate;
a suction configured to suck residues generated from the bonding substrate; and
a controller configured to control a position of the waterjet cutting unit, a pressure of the fluid, a type of the fluid, and an operation of the suction based on parameters of the bonding substrate, which are measured by the camera unit, and
the waterjet cutting unit includes a water body through which ultrapure water passes, an abrasive supplying unit configured to supply an abrasive, an abrasive body storing the abrasive received from the abrasive supplying unit, an orifice through which the ultrapure water passes, a mixing tube in which the ultrapure water and the abrasive are mixed, and a position adjusting unit configured to adjust at least one of a position or an angle of the fluid to be discharged.

19. The substrate processing equipment of claim 18, wherein the bonding substrate includes a first substrate and a second substrate, and at least one of the first substrate or the second substrate includes at least two layers having different hardnesses from each other.

20. The substrate processing equipment of claim 18, wherein the pressure of the fluid is in a range from about 4,100 bar to about 6,400 bar.
